(19) United States
(12) Patent Application Publication
(10) Pub. No.: US 2019/0103543 A1
(43) Pub. Date: Apr. 4, 2019

(54) Superconductor Device for Operation in an External Magnetic Field

(71) Applicant: Siemens Aktiengesellschaft, Muenchen (DE)

(72) Inventors: Tabea Arndt, Erlangen (DE); Marijn Pieter Oomen, Erlangen (DE)

(73) Assignee: Siemens Aktiengesellschaft, Muenchen (DE)

(21) Appl. No.: 16/086,893

(22) PCT Filed: Mar. 22, 2017
(86) PCT No.: PCT/EP2017/056770

§ 371 Date: Sep. 20, 2018

(30) Foreign Application Priority Data
Mar. 24, 2016 (DE) 10 2016 204 991.7

(51) Int. Cl. H01L 39/14; H01L 39/12

(52) U.S. Cl. CPC H01L 39/143; H01L 39/126

(57) ABSTRACT

Various embodiments may include a superconductor device for operation in an external alternating magnetic field comprising: two superconducting contact elements; a current-conducting section connecting the elements in a longitudinal direction corresponding to the direction of the flow of current; a superconductor layer applied to a substrate including a recess defining individual filaments. The individual filaments define current paths. At least two adjacent filaments are conductively connected in a crossing region formed on the substrate. The crossing region connects four current paths through omission of the recess. The device also includes a resistance barrier in a current paths of two adjacent filaments, which current paths are opposite with respect to the crossing and offset in the longitudinal direction and a transverse direction, perpendicular to the longitudinal direction, of a plane of the layer.

### CROSS-REFERENCE TO RELATED APPLICATIONS

This application is a U.S. National Stage Application of International Application No. PCT/EP2017/056770 filed Mar. 22, 2017, which designates the United States of America, and claims priority to DE Application No. 10 2016 204 991.7 filed Mar. 24, 2016, the contents of which are hereby incorporated by reference in their entirety.

### TECHNICAL FIELD

The present disclosure relates to superconductor devices. Various embodiments may be suitable for operation in an external alternating magnetic field.

### BACKGROUND

The use of superconductors has been proposed in alternating magnetic fields, for example in superconducting electric machines. When electrical conductors are used in alternating magnetic fields, alternating field losses occur, which can be grouped into various components according to the physical causes. In the case of superconductors, there are additional effects/components compared to normal conductors. In cold operating conditions, said alternating field losses can be particularly interfering and prohibitive for application, since a multiple of the alternating field losses is then required at room temperature, which reduces the efficiency.

In the case of normal conductors, it is not a monolithic conductor but a Litz-wire conductor that is usually used in alternating magnetic field. This minimizes the disadvantageous consequences of skin effect and eddy current losses. In the case of superconductors, which are often produced from billets or bolts, for example NbTi, Nb3Sn, MgB2 or Bi-2223, may include superconducting filaments. Filaments in superconductors not only result in a positive increase in the stability of the superconductivity, but can also reduce the magnetic field losses.

In the case of superconductors, the so-called hysteresis losses come about by virtue of the fact that magnetic fields that penetrate into the conductor change their direction with the outer alternating magnetic field and consequently remagnetization processes have to take place. Since the extent of the superconductor perpendicular to the magnetic field determines the magnitude of the hysteresis losses, a formation of thin filaments may help. However, the filaments in superconductors are usually electrically connected to one another, on the one hand, forcibly at the ends by way of the contacts at which the current is fed in and conducted out, and, where necessary, on the other hand, by way of the (resistive) normally conducting matrix. The alternating field losses associated therewith are called coupling losses.

In the case of such filamentation and coupling by way of the contact elements and/or the matrix, coupling between the individual filaments occurs, that is to say, in particular, due to the outer alternating magnetic field, voltages and currents are induced in conductor loops formed by the filaments together with connections between them at contact elements, as a result of which the coupling losses arise. For normal conductors and multifilament superconductors, it is therefore known to twist these with respect to one another so that the electrical fields arising on account of the alternating magnetic field are canceled out in adjacent loops. This concept is also known as a “twisted pair”.

Such a configuration is not possible in layer superconductors, which are applied to a substrate as a layer. To reduce the hysteresis losses, some systems subdivide the superconductor layer, originally continuous in width, in the longitudinal direction into strips, so-called “striations”. This is described, for example, in an article by Coleman B. Cobb et al., “Hysteretic loss reduction in striated YBCO”, Physica C 382 (2002), pages 52-56.

The layer superconductors, which can have widths of up to 1 cm, do not have acceptable hysteresis losses during operation in alternating magnetic fields perpendicular to the layer. The way in which said hysteresis losses behave in the case of subdivision of the superconductor layer into thin, linear filaments (“striations”) is investigated. In general, the result is that, although the hysteresis losses can be reduced since the dimension of the filaments perpendicular to the field direction is the determining factor for this, in a real application in which the filaments are shorted at least at the beginning and end in each case by electrical contact elements (or by matrix and shunt layer), these so-called “striated conductors” between the filaments have large induction loops, which in turn are the cause of increased alternating magnetic field losses (coupling losses). The filaments thus essentially correspond to “untwisted” conductor elements with electrical connection at the contacts.

### SUMMARY

The teachings herein, therefore, may provide an option for reducing the coupling losses in the case of superconductor layers that are to be subdivided into individual filaments. For example, some embodiments include two superconducting contact elements and a current-conducting section, which connects said contact elements in a longitudinal direction corresponding to the direction of the flow of current from one contact element to the other contact element and which has a superconductor layer applied to a substrate, wherein the superconductor layer is at least partly severed in the longitudinal direction by means of a recess in order to form individual filaments, which form current paths for the transport current.

For example, some embodiments include a superconductor device (1a, 1b) for operation in an external alternating magnetic field, having two superconducting contact elements (2) and a current-conducting section (5), which connects said contact elements in a longitudinal direction corresponding to the direction of the flow of current from one contact element (2) to the other contact element (2) and which has a superconductor layer applied to a substrate (8), wherein the superconductor layer is at least partly severed in the longitudinal direction by means of a recess (4) in order to form individual filaments (3), which form current paths for the transport current, characterized in that at least two of the filaments (3) that are adjacent are conductively connected in a crossing region (6), which is formed on the substrate (8) and at which four current paths are conductively connected, through omission of the recess (4), wherein at least one, in particular in each case one, ohmic resistance barrier (7) is provided in current paths of the adjacent filaments (3), which current paths are opposite with respect to the crossing and offset in the longitudinal direction and a transverse direction, perpendicular to the longitudinal direction, of the layer plane.

In some embodiments, an even number of filaments (3) is provided, wherein the filaments (3) are divided into disjoint filament groups (16) each containing two adjacent filaments (3) and filaments (3) of a filament group (16) are connected by means of at least one crossing region (6), in particular an odd number of crossing regions (6).

In some embodiments, the resistance vales of the at least one resistance barrier (7) are each selected so that an ohmic power loss is smaller in absolute terms than a reduction in the power loss on account of a coupling of adjacent filaments (3). In some embodiments, the resistance values are calculated through a simulation and/or in a model and/or are determined through evaluation of test measurements.

In some embodiments, the at least one resistance barrier (7) is realized through a laser treatment and/or a mechanical treatment of the layer and/or a localized doping or depletion of the layer and/or through use of a local coating and/or of a structure in the substrate (8) that weakens the superconductivity.

In some embodiments, at least one resistance barrier (7) is arranged directly adjacent to the respective crossing region (6).

### BRIEF DESCRIPTION OF THE DRAWINGS

Further features and details of the present disclosure emerge from the exemplary embodiments described in the following text and with reference to the drawing, in which:

FIG. 1 shows a first embodiment of a superconductor device according to the teachings herein;

FIG. 2 shows the current profile in different current paths according to the teachings herein;

FIG. 3 shows a second embodiment of a superconductor device according to the teachings herein; and FIG. 4 shows a plurality of crossing regions in a filament group according to the teachings herein.

### DETAILED DESCRIPTION

A superconductor device may include at least two filaments that are adjacent conductively connected in a crossing region, which is formed on the substrate and at which four current paths are conductively connected, through omission of the recess, wherein at least one, in particular in each case one, ohmic resistance barrier is provided in current paths of the adjacent filaments, which current paths are opposite with respect to the crossing and offset in the longitudinal direction and a transverse direction, perpendicular to the longitudinal direction, of the layer plane and meet at the crossing.

In some embodiments, there may be in each case one resistance barrier. At least below the critical current of a filament, a current path that alternates the filament at the crossing region and that uses the barrier-free current routes arises. The barriers thus constrain in the crossing region current paths that alternate the side, that is to say the filament, so that, in conductor loops separated by a crossing region and formed by the current routes, voltages that are respectively opposed and identical in terms of the magnitude in the case of a symmetrical configuration are generated through a current path on account of the electrical fields generated by the temporally varying outer magnetic field components located perpendicular to the layer plane.

In other words, the crossing regions and the resistance barriers generate two current paths that cross one another in the crossing region, along which two current paths the electrical fields (and hence also the induced voltages) cancel out in the case of a symmetrical configuration, that is to say four geometrically at least similar current routes. In this case, the effect is, at least in the range up to the critical current of a filament, the same as would also arise if a bridge, which is isolated from the other current path, to the other filament were provided.

In some embodiments, there is a two-dimensional, in-plane realization of “twisting” of current paths with respect to one another. In some embodiments, as considered along a current path, the electrical fields cancel out at least for the most part, in the case of corresponding symmetry cancel out completely. A layer superconductor may have not simply just linear filaments/striations that completely define the current paths, but the current paths cross one another in the layer plane in a defined manner in such a way that the induced electrical fields along the current paths mutually at least partly cancel out. The resistance barriers, which are local regions of defined resistance value, consequently lead to decoupling of the current paths. Although resistance barriers of this kind result for some current values in a purely resistive loss component in phase with the transport current, said purely resistive loss component is (which will be dealt with in more detail in the following text) expediently kept lower than the coupling losses in pure “striated conductors”, wherein the latter additionally also are or can be phase-shifted.

In some embodiments, the configuration described produces an asymmetrical current distribution across the two current paths so that an asymmetrical division of the partial currents of the total current occurs at least temporarily. Therefore, only the first current path that is free from resistance barriers will initially be used until the critical current of a single filament is reached and the resistance-free current transport is exhausted here. The second current path, in which the two resistance barriers have to be overcome, then proves to be more advantageous and the current increases here, ideally likewise up to the critical current of a filament. The second current path takes over, as it were, the “excess current”, wherein the second current path still has the task of compensating for the induced electrical field so that a reduction of the alternating field losses at least partly arises.

Opposing the advantage of lower alternating field losses are two restrictions, but restrictions that are to have a lower weighting in relation thereto, specifically, on the one hand, a possible reduction in the current density with respect to the total cross section of the superconductor device due to the particular configuration. On the other hand, as has already been indicated, the current transport with respect to the second current path is affected via the preferably two resistance barriers, which can have a resistivity and hence losses of an ohmic type. However, these may be in phase with the transport current - in contrast with the coupling losses on account of induction.

In some embodiments, when at least one resistance barrier is used only on one side, the clear division into the different current paths is present only on one side; nevertheless, electrical fields are at least partly canceled out. However, in some embodiments, as said, there are resistance barriers on both sides of the crossing region, as already mentioned above.

While it is conceivable in theory to construct complex networks of current paths in the case of a multiplicity of filaments through the use of crossing regions, this is, however, unnecessary and significantly too complex in the end since it is ultimately sufficient, for achieving the reduction in the coupling losses (alternating field losses), to reproduce a “twisted pair”, that is to say current paths twisted with respect to one another, using in each case two filaments in the layer plane. In some embodiments, there is an even number of filaments, wherein the filaments are divided into disjoint filament groups each containing two adjacent filaments and filaments of a filament group are connected by means of at least one crossing region, in particular an odd number of crossing regions. In the case of a very high number of crossing regions over the length of the conductor, however, the even or odd number of crossing regions is insignificant. If a current-conducting section consequently has, for example, six filaments, three groups of respectively adjacent filaments are formed, which each have at least one crossing region, and consequently two current paths that cross in the at least one crossing region are formed. An odd number of crossing regions means that an even number of conductor loops are formed so that the electrical field induced by the alternating magnetic field always alternately meets the current in opposite directions so that, in the case of a symmetrical configuration, the effects are ideally canceled out. In this case, the resistance barriers in the case of a plurality of crossing regions are to be arranged in such a way that a current path that does not conduct via any of the resistance barriers is always produced. In some embodiments, the electrical connection is always produced between the two filaments of a filament group in the crossing region and the corresponding resistance barriers may be provided in offset fashion.

In some embodiments, the resistance values of the at least one resistance barrier may be selected so that an ohmic power loss is smaller in absolute terms than a reduction in the power loss on account of a coupling of adjacent filaments. In this case, the resistance values can be, for example, in a range of less than 0.5 nΩ, in particular of less than 0.1 nΩ. Using externally produced contacts on high-temperature superconductors, ranges of approximately 6 nΩ are easily reached so that the mentioned lower values for the individual resistance barriers also appear to be easily achievable. The coupling losses (alternating field losses) are not simply replaced by in-phase ohmic resistance losses but an overall reduction in the losses actually takes place. Resistance values for the individual resistance barriers can also be roughly estimated by virtue of a comparison with a conventional “striated conductor” having filaments that are not connected in crossing regions being carried out.

Assuming, for example, six filaments having a length of 0.1 m, a substrate width of 0.012 m, a filament separation (width of the recess) of 10 μm and a thickness of the superconducting layer on the substrate of 3 μm, the final result from the law of induction and in the case of an assumed total current of 120 A is a power loss density of 10⁷ W/m³. Since five such “induction loops” (due to five adjacent pairs of filaments) exist, it is possible to estimate a maximum of the ohmic power loss density in such a way that five times the coupling losses just mentioned is not to be exceeded, wherein, in the example mentioned, the result is approximately 0.6 nΩ. Since, as illustrated, resistance values in this range are easily achievable, it is demonstrated that such a conductor design can be advantageous compared to a “striated conductor” or a monolithic conductor.

In some embodiments, the resistance values may be calculated through a simulation and/or in a model and/or to be determined through evaluation of test measurements, that is to say empirically. Programmed simulation environments that already exist can expediently be used to observe the behavior of the superconductor device, the losses and currents in the case of different resistance values in such a way that an optimum resistance value is found.

In some embodiments, the at least one resistance barrier may be realized through a laser treatment and/or a mechanical treatment of the layer and/or a localized doping/depletion of the layer and/or through use of a local coating and/or of a structure in the substrate that weakens the superconductivity. Consequently, many options that are known in principle in the field of superconductivity technology are conceivable in order to generate resistance barriers of low resistance in filaments in a targeted and local manner. In some embodiments, a laser, since it is known, for example, may be used to generate the recesses between the individual filaments likewise through a laser and thus also the barriers through a (less intensive) use of the laser being able to be performed in the spatial resistance region provided for the resistance barrier on the remaining filament. In some embodiments, the at least one resistance barrier is arranged directly adjacent to the respective crossing region, since a particularly clear definition of the current paths is then made possible.

In this case, it should be noted that it is entirely possible to deviate from a linear continuous profile of the filaments but this is not absolutely necessary. In some embodiments, a recess or groove through the superconductor layer separates filaments from one another, being formed so as not to be continuous over the entire length of the current-conducting section but having interruptions at the desired crossing regions so that the crossing regions are produced accordingly. In addition, a corresponding lateral narrowing of the crossing region can also nevertheless be desired and provided, of course. If the deviation from the linear profile of the individual filaments is as small as possible, the most space-saving realization possible of the present invention is produced.

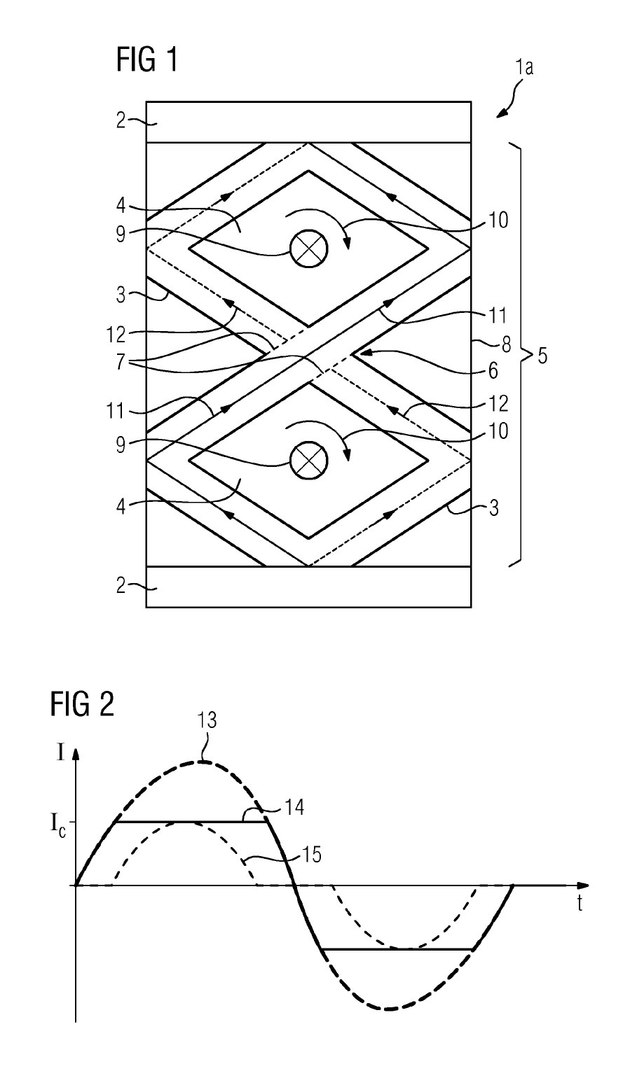

FIG. 1 shows an exemplary embodiment of a superconductor device 1a according to the teachings herein, which is extremely simple and suitable for explanation, in which superconductor device evidently two filaments 3 that connect two contact elements 2 are provided, which filaments are separated by recesses 4. The plane of the drawing of FIG. 1 is in this case the layer plane of the superconductor layer. The current-conducting section 5 is situated between the contact elements 2, as is known.

However, the filaments 3 are not separated over the entire current-conducting section 5 here but are electrically conductively connected centrally in a crossing region 6 to form overall a symmetrical configuration. However, this symmetry is broken by the crossing region 6 of directly adjacent resistance barriers 7, which are opposite with respect to the crossing region 6, transversely and longitudinally offset and provided locally in resistance regions. The resistance barriers 7 have an extremely low ohmic resistance value, in the present case in the range of less than 0.1 nΩ, and have been generated through laser treatment, wherein other options for generation are also conceivable, however. In the present case, YBCO is used as superconductor material of the superconductor layer, which is arranged on the substrate 8.

An outer alternating magnetic field runs according to the arrows 9 perpendicular to the layer plane and, as a result, that is to say on account of the temporary change, can induce an electrical field, indicated by arrows 10. The resistance barriers 7 now initially force the use of a first current path, characterized by solid arrows 11, which first current path consequently alternates in the crossing region 6 from the left filament 3 to the right filament 3, wherein the present case illustrates a situation in which the transport current runs from the bottom upward in FIG. 1. If the critical current of a filament 3 is exceeded, the second current path, which conducts via the resistance barriers 7 and is characterized by dashed arrows 12, is also used. The first and the second current path thus cross in the crossing region 6 so that overlapping current paths in the layer plane of the superconductor layer can be thus created by the resistance barriers 7 and the crossing region 6. In this current conduction, the electrical fields (arrows 10) are each canceled out along the first current path and the second current path since, as can be clearly seen, the electrical field (arrow 10) for the respective current path is induced in the two “meshes” or conductor loops once in the direction of the partial current and once counter to this direction. This means that the effect of the outer alternating magnetic field and hence the coupling losses are neutralized.

However, as has already been indicated, the partial currents of the current paths are divided asymmetrically at least temporarily, as can be seen from the current profiles in FIG. 2. Curve 13 corresponds here to the total current, the maximum of which ideally corresponds in absolute terms substantially to two times the critical current of a filament 3. Curve 14 shows the profile of the partial current for the first current path (arrows 11 in FIG. 1); curve 15 shows the profile for the second current path (arrows 12 in FIG. 1). Until the critical current I_{c} in the first current path has been reached, current flows only in the first current path, then the second current path takes on the excess current; in the case of the falling total current edge, the opposite occurs accordingly. Nevertheless, the second current path fulfills the task of compensating for the induced electrical field so that the advantageous reduction of the coupling losses at least partly takes place.

The current paths or filaments do not necessarily have to diverge in such a strongly pronounced manner as is illustrated in the first exemplary embodiment of FIG. 1 that is explained. It only has to be ensured that the resistance barriers 7 force the flow of current illustrated.

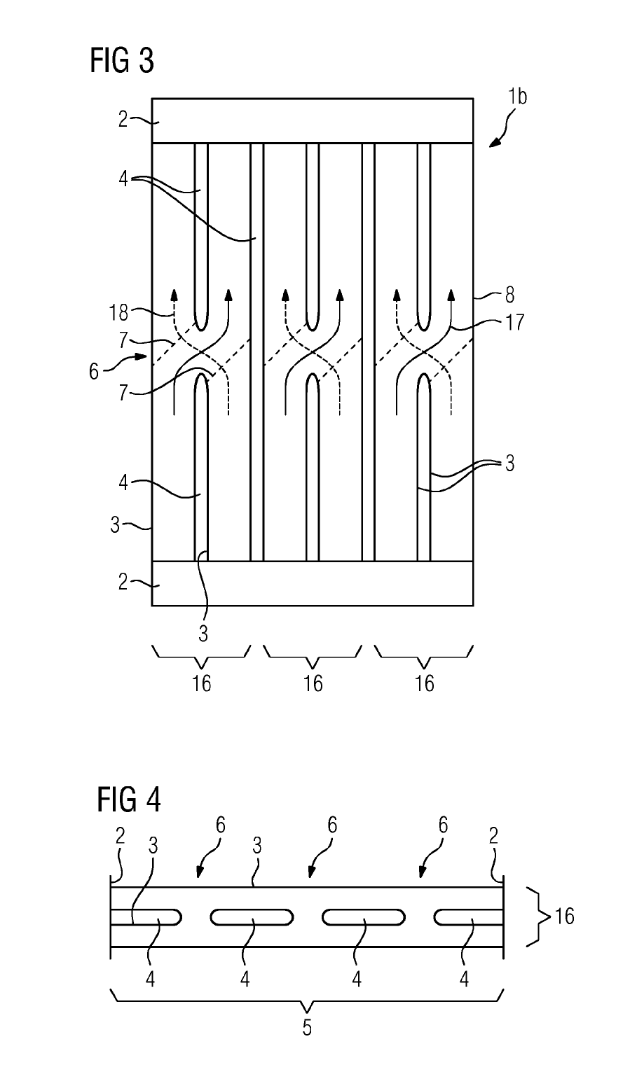

FIG. 3 accordingly shows a second embodiment of a superconductor device 1b according to the teachings herein, wherein the reference signs of FIG. 1 have been retained for corresponding components for the sake of simplicity. In contrast to the illustration of FIG. 1, six filaments 3 are provided here, which are divided into three filament groups 16 of in each case two adjacent filaments 3. The recess 4 is continuous between the filament groups 16 whereas the recess 4 is interrupted within the filament groups 16 for the purpose of forming the crossing regions 6, wherein a possible profile of the resistance barriers 7 is also indicated accordingly. Correspondingly, the flow of current is also forced here according to the first current path, cf. here arrow 17, and in the second current path, cf. here arrow 18, again dashed. The crossing regions 6 are each located in the center of the current-conducting section 5 so that respectively opposite electrical field arise along the current paths at identical lengths.

In this case, the number of crossing regions 6 does not necessarily have to be restricted to one, as the schematically illustrated filament pair 16 of FIG. 4 shows. Here, three crossing regions 6, which are distributed equidistantly over the length of the current-conducting section 5, are realized. Conductor loops, composed of geometrically identical current routes, are thus produced and consequently induced electrical fields along the current paths alternating the filaments, which electrical fields cancel out in optimum fashion in terms of their effects.

Although the teachings herein have been illustrated and described in more detail by way of the example embodiments, the scope of those teachings is not restricted by the disclosed examples and other variations can be derived herefrom by the person skilled in the art without departing from the scope.

What is claimed is:

1. A superconductor device for operation in an external alternating magnetic field, the device comprising:
two superconducting contact elements;
a current-conducting section connecting the two contact elements in a longitudinal direction corresponding to the direction of the flow of current from one contact element to the other contact element;
a superconductor layer applied to a substrate, the superconductor layer at least partly severed in the longitudinal direction by a recess defining individual filaments;
wherein the individual filaments define current paths for the transport current;
wherein at least two adjacent filaments are conductively connected in a crossing region formed on the substrate;
wherein the crossing region connects four current paths through omission of the recess;
at least one ohmic resistance barrier in current paths of the at least two adjacent filaments, which current paths are opposite with respect to the crossing and offset in the longitudinal direction and a transverse direction, perpendicular to the longitudinal direction, of a plane of the layer.

2. The superconductor device as claimed in claim 1, comprising an even number of individual filaments divided into disjoint filament groups each containing two adjacent filaments;
wherein filaments of one of the disjoint filament groups are connected by at least one crossing region.

3. The superconductor device as claimed in claim 1, wherein resistance vales of the at least one resistance barrier provide an ohmic power loss smaller than a reduction in the power loss on account of a coupling of adjacent filaments.

4. The superconductor device as claimed in claim 3, wherein the resistance values are calculated through a simulation and/or in a model and/or are determined through evaluation of test measurements.

5. The superconductor device as claimed in claim 1, wherein the at least one resistance barrier is realized through a laser treatment and/or a mechanical treatment of the layer and/or a localized doping or depletion of the layer and/or through use of a local coating and/or of a structure in the substrate that weakens the superconductivity.

6. The superconductor device as claimed in claim 1, further comprising at least one resistance barrier arranged directly adjacent to the respective crossing region.
